(19) United States
(12) Patent Application Publication
(10) Pub. No.: US 2009/0004774 A1
(43) Pub. Date: Jan. 1, 2009

(54) METHOD OF MULTI-CHIP PACKAGING IN A TSOP PACKAGE

(76) Inventors: Ming Hsun Lee, Taichung (TW); Cheemen Yu, Madison, WI (US)

Correspondence Address: VIERRA MAGEN/SANDISK CORPORATION, 575 MARKET STREET, SUITE 2500, SAN FRANCISCO, CA, 94105, US

(21) Appl. No.: 11/769,158

(22) Filed: Jun. 27, 2007

(51) Int. Cl. H01L 21/60

(52) U.S. Cl. 438/107; 438/123; 257/E21.506

(57) ABSTRACT

A method of fabricating a semiconductor package, and a semiconductor package formed thereby, are disclosed. The semiconductor package may include a leadframe having one or more semiconductor die and one or more passive components affixed thereon. The one or more passive components may be affixed by soldering with a solder material. In embodiments, in order to prevent bleeding of the solder material during a solder reflow process, barricades are formed on the surface of the leadframe, at least partially surrounding the one or more passive components.

### CROSS-REFERENCE TO RELATED APPLICATION

The following application is cross-referenced and incorporated by reference herein in its entirety:

U.S. patent application Ser. No. ______ [Attorney Docket No. SAND-01256US1], entitled “Multi-Chip Packaging In A TSOP Package,” by Ming Hsun Lee, et al., filed on even date herewith.

### BACKGROUND OF THE INVENTION

1. Field of the Invention

Embodiments of the present invention relate to a method of fabricating a semiconductor package, and a semiconductor package formed thereby.

2. Description of the Related Art

As the size of electronic devices continue to decrease, the associated semiconductor packages that operate them are being designed with smaller form factors, lower power requirements and higher functionality. Currently, sub-micron features in semiconductor fabrication are placing higher demands on package technology including higher lead counts, reduced lead pitch, minimum footprint area and significant overall volume reduction.

One branch of semiconductor packaging involves the use of a leadframe, which is a thin layer of metal on which one or more semiconductor die may be mounted. The leadframe includes electrical leads for communicating electrical signals from the one or more semiconductors to a printed circuit board or other external electrical devices. Common leadframe-based packages include plastic small outlined packages (PSOP), thin small outlined packages (TSOP), and shrink small outline packages (SSOP). Components in a conventional leadframe package are shown in FIGS. 1 and 2. The illustrated components may be used for example in a TSOP package, which comes standard in 32-lead, 40-lead, 48-lead and 56-lead packages (fewer leads are shown in the figures for clarity).

FIG. 1 shows a leadframe 20 before attachment of a semiconductor die 22. A typical leadframe 20 may include a number of leads 24 having first ends 24a for attaching to semiconductor die 22, and a second end (not shown) for affixing to a printed circuit board or other electrical component. Leadframe 20 may further include a die attach pad 26 for structurally supporting semiconductor die 22 on leadframe 20. While die attach pad 26 may provide a path to ground, it conventionally does not carry signals to or from the semiconductor die 22. In certain leadframe configurations, it is known to omit die attach pad 26 and instead attach the semiconductor die directly to the leadframe leads in a so-called chip on lead (COL) configuration.

Semiconductor leads 24 may be mounted to die attach pad 26, as shown in FIG. 2, using a die attach compound. Semiconductor die 22 is conventionally formed with a plurality of die bond pads 28 on first and second opposed edges on the top side of the semiconductor die. Once the semiconductor die is mounted to the leadframe, a wire bond process is performed whereby bond pads 28 are electrically coupled to respective electrical leads 24 using a delicate wire 30. The assignment of a bond pad 28 to a particular electrical lead 24 is defined by industry standard specification. FIG. 2 shows less than all of the bond pads 28 being wired to leads 24 for clarity, but each bond pad may be wired to its respective electrical lead in conventional designs. It is also known to have less than all of the bond pads 28 wired to the electrical leads 24 as shown in FIG. 2. Once wire bonding is completed, a molding process may be performed to encase the components in a finished semiconductor package including leads protruding from the package which may be surface mounted to a printed circuit board.

As seen in FIGS. 1 and 2, it is also known to mount one or more passive components 34 on the surface of the leadframe 20. Passive components 34 may for example include capacitors, resistors, inductors, etc. The passive components may be mounted to contact pads coupled to leads 24 as by soldering. An example of passive components mounted on a leadframe is disclosed for example in U.S. Pat. No. 5,281,846, entitled, “Electronic Device Having a Discrete Capacitor Adherently Mounted to a Leadframe.”

When soldering the passive components to the leadframe, it is a problem in the prior art to limit the solder specifically to those areas where it is needed to affix the passive components 34. In particular, solder bleeding occurs where there is solder wetting in a location other than the desired location of the solder fillet. Excess solder may lead to electrical shorting and other reliability problems with the semiconductor package. One solution is to limit the amount of solder used. However, low solder volume may lead to poor electrical and/or physical coupling of the passive components to the leadframe, and can also cause reliability problems in the semiconductor package.

### SUMMARY OF THE INVENTION

Embodiments of the present invention in general relate to a method of fabricating a semiconductor package, and a semiconductor package formed thereby. In embodiments, the semiconductor package is a portable memory including a leadframe having one or more semiconductor die and one or more passive components affixed thereon. The one or more passive components may be affixed by soldering with a solder material. In embodiments, in order to prevent bleeding of the solder material during a solder reflow process, barricades are formed on the surface of the leadframe, at least partially surrounding the one or more passive components.

In embodiments, the barricades may be formed of an electrically insulating material, such as solder mask or polyimide tape, and may be applied to the surface of the leadframe by various processes, including printing, lamination or by a deposition process.

In alternative embodiments, instead of a barricade extending above the surface of the leadframe, solder bleeding may be prevented with a recessed section at least partially surrounding the one or more passive components. The recessed section may be formed by a variety of half-etch processes into the surface of the leadframe including by laser etching, chemical etching or by routing.

### BRIEF DESCRIPTION OF THE DRAWINGS

FIG. 1 is an exploded perspective view a conventional leadframe and semiconductor die.

FIG. 2 is perspective view of a conventional semiconductor die and passive components coupled to a conventional leadframe.

FIG. 3 is an exploded perspective view of a semiconductor package (without molding compound) including passive components affixed to the leadframe according to embodiments of the present invention.

FIG. 4 is a perspective view of a semiconductor package (without molding compound) including passive components mounted to a leadframe according to embodiments of the present invention.

FIG. 5 is a partial top view of a leadframe including solder bleed barriers according to embodiments of the present invention.

FIG. 6 is a side view of a portion of the leadframe through line 6-6 in FIG. 5 and showing a passive component space therefrom.

FIG. 7 is a side view of a portion of the leadframe as in FIG. 6 showing the solder bleed barricades limiting the applied solder paste to desired locations.

FIG. 8 is a top view of a portion of the leadframe as in FIG. 5 showing the solder bleed barricades limiting the applied solder paste to desired locations.

FIG. 9 is a top view of a recessed portion formed in the leadframe for confining the solder paste to desired locations according to an alternative embodiment of the present invention.

FIG. 10 is a cross sectional side view through line 10-10 in FIG. 9 showing a passive component spaced from the leadframe including a recessed portion.

FIG. 11 is a side view of a portion of the leadframe as in FIG. 10 showing the solder bleed barricades limiting the applied solder paste to desired locations.

FIG. 12 is a top view of a portion of the leadframe as in FIG. 9 showing the solder bleed barricades limiting the applied solder paste to desired locations.

FIG. 13 is a top view of a recessed portion formed in the leadframe for confining the solder paste to desired locations according to a further alternative embodiment of the present invention.

FIG. 14 is a cross sectional side view through line 14-14 in FIG. 13 showing a passive component spaced from the leadframe including a recessed portion.

FIG. 15 is a side view of a portion of the leadframe as in FIG. 14 showing the solder bleed barricades limiting the applied solder paste to desired locations.

FIG. 16 is a cross sectional view of a finished semiconductor package according to embodiments of the present invention.

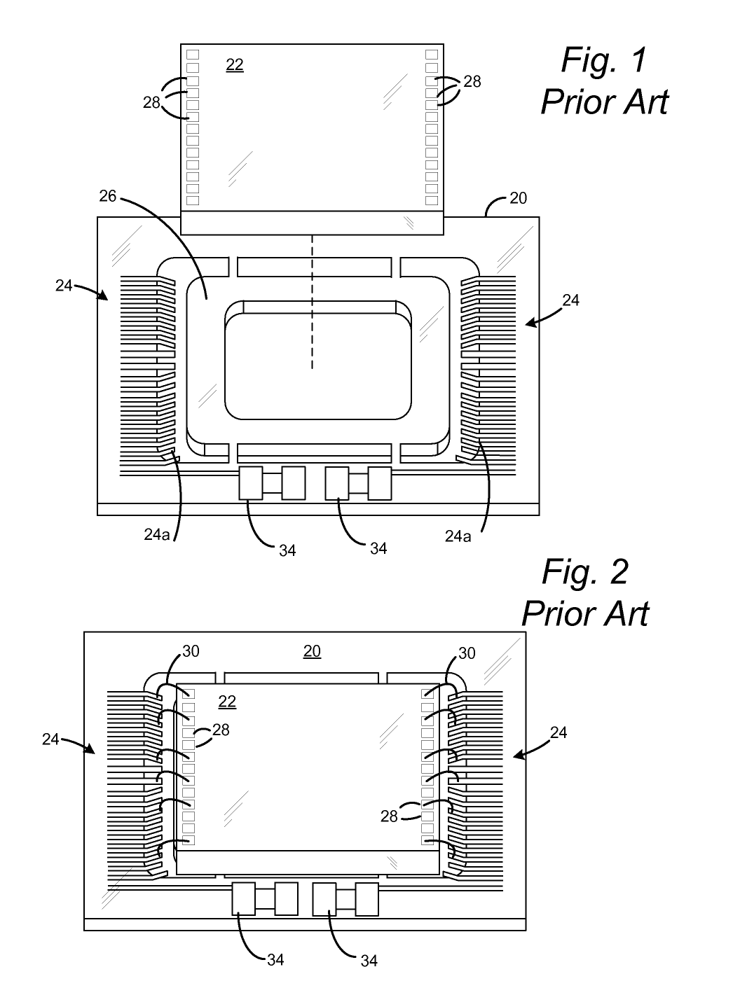

### DETAILED DESCRIPTION

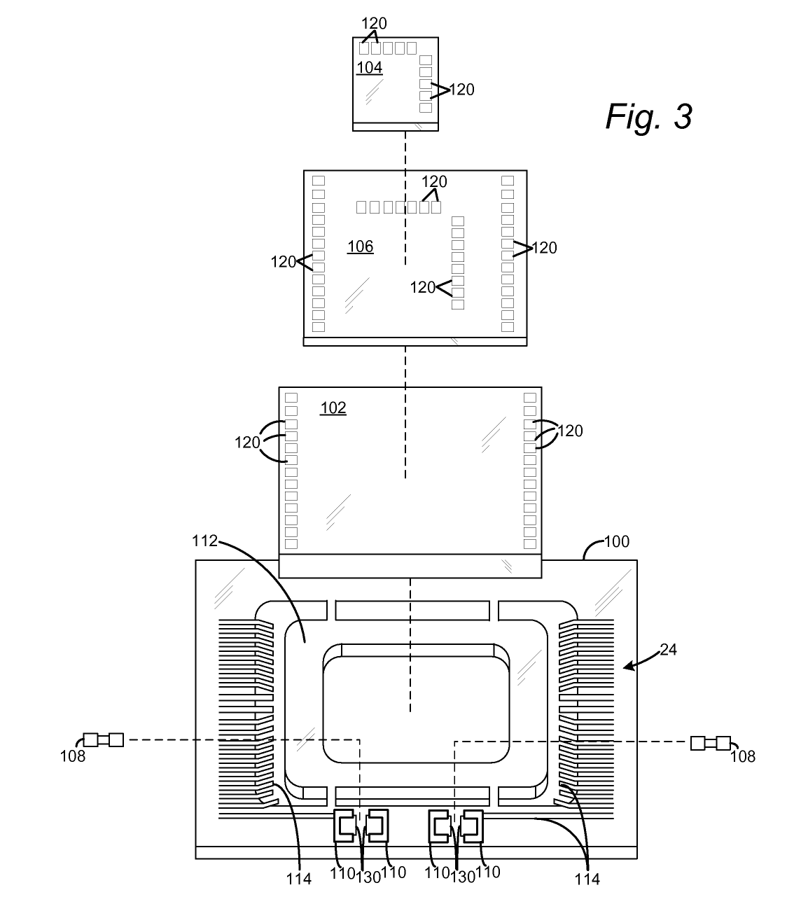

Embodiments of the present invention will now be described in reference to FIGS. 3-16 which in general relate to a method of fabricating a semiconductor package, and a semiconductor package formed thereby. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 3 is an exploded perspective view of a leadframe 100, semiconductor die 102 and 104, interposer 106, passive components 108 and solder-bleed barricades 110 according to embodiments of the invention. In general, the leadframe 100 according to the present invention may be batch processed from a panel of such leadframes to achieve economies of scale. Leadframe 100 includes a die paddle 112 for supporting one or more semiconductor die. Leadframe 100 further includes electrical leads 114 for communicating electrical signals to and from the one or more semiconductor die 102, 104, the passive components 108 and an external electronic device, such as a printed circuit board, on which the finished package is mounted.

Leadframe 100 may be formed of a planar or substantially planar piece of metal, such as copper or copper alloys, plated copper or plated copper alloys, Alloy 42 (42 Fe/58 Ni), or copper plated steel. Leadframe 100 may be formed of other metals and materials known for use in leadframes. In embodiments, leadframe 100 may also be plated with silver, gold, nickel palladium, or copper.

Leadframe 100 may be formed by known fabrication processes, such as for example, chemical etching. In chemical etching, a photoresist film may be applied to the leadframe. A pattern photomask containing the outline of the die paddle 112, leads 114 and other features of leadframe 100 may then be placed over the photoresist film. The photoresist film may then be exposed and developed to remove the photoresist from areas on the conductive layers that are to be etched. The exposed areas are next etched away using an etchant such as ferric chloride or the like to define the pattern in the leadframe 100. The photoresist may then be removed. Other known chemical etching processes are known. The leadframe 100 may alternatively be formed in a mechanical stamping process using progressive dies. As is known, mechanical stamping uses sets of dies to mechanically remove metal from a metal strip in successive steps.

After formation of the leadframe, one or more semiconductor die 102, 104 may be mounted to the die paddle 112 of leadframe 100. Although not critical to the present invention, the semiconductor die 102 may be a flash memory chip (NOR/NAND) and semiconductor die 104 may be a controller chip such as an ASIC. More than one memory die 102 may be included in alternative embodiments, and controller die 104 may be omitted in alternative embodiments. Moreover, it is understood that the leadframe 100 and one or more die 102 and/or 104 may be used in a variety of different semiconductor packages. Interposer layer 106 may be included for transferring signals for example from controller die 104 to the leads 114 on leadframe 100 as is known in the art. Interposer layer 106 may be omitted in alternative embodiments.

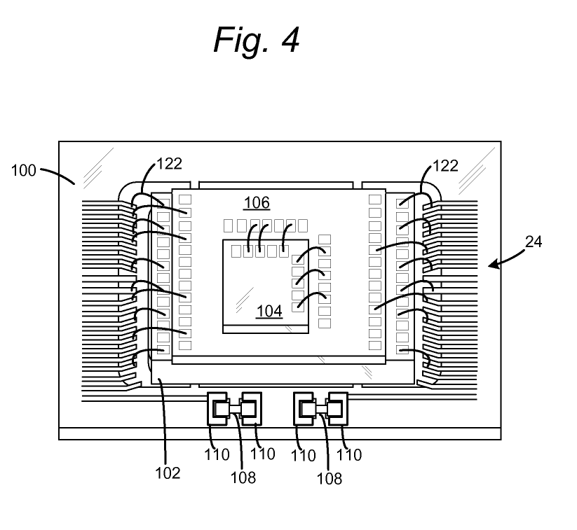

Referring now to FIGS. 3 and 4, the one or more semiconductor die 102, 104 may be mounted to leadframe 100 in a known manner using a dielectric die attach compound, film or tape. The die 102, 104 and interposer layer 106 may each include die bond pads 120 receiving bond wires 122 (some of which die bond pads and bond wires are labeled in FIGS. 3 and 4). The bond wires 122 are provided in a known wire bond process to electrically couple the semiconductor die 102, 104 to the electrical leads 114. It is understood that greater or fewer bond wires 122 may be included than are shown in alternative embodiments.

Leadframe 100 further includes passive component bond pads 130 to which passive components 108 may be mounted. Passive components 108 may be any of a variety of passive components including for example capacitors, resistors, inductors, etc. Passive components 108 may be soldered to contact pads 130 as shown in FIG. 4 using a known material, such as solder paste, solder balls or other known types of solder. The soldering process may include providing solder material on contact pads 130, positioning passive components 108 on the solder material and then heating the leadframe, solder material and passive components 108 in a known solder reflow process.

The reflow process liquefies and hardens the solder material, thereby physically and electrically coupling passive components 108 to contact pads 130. It is understood that other electrically conductive and flowable materials may be used instead of solder material to electrically and physically couple passive components 108 to contact pads 130 in alternative embodiments. In embodiments, passive components 108 may be affixed to leadframe 100 prior to the die 102, 104 being affixed to leadframe 100.

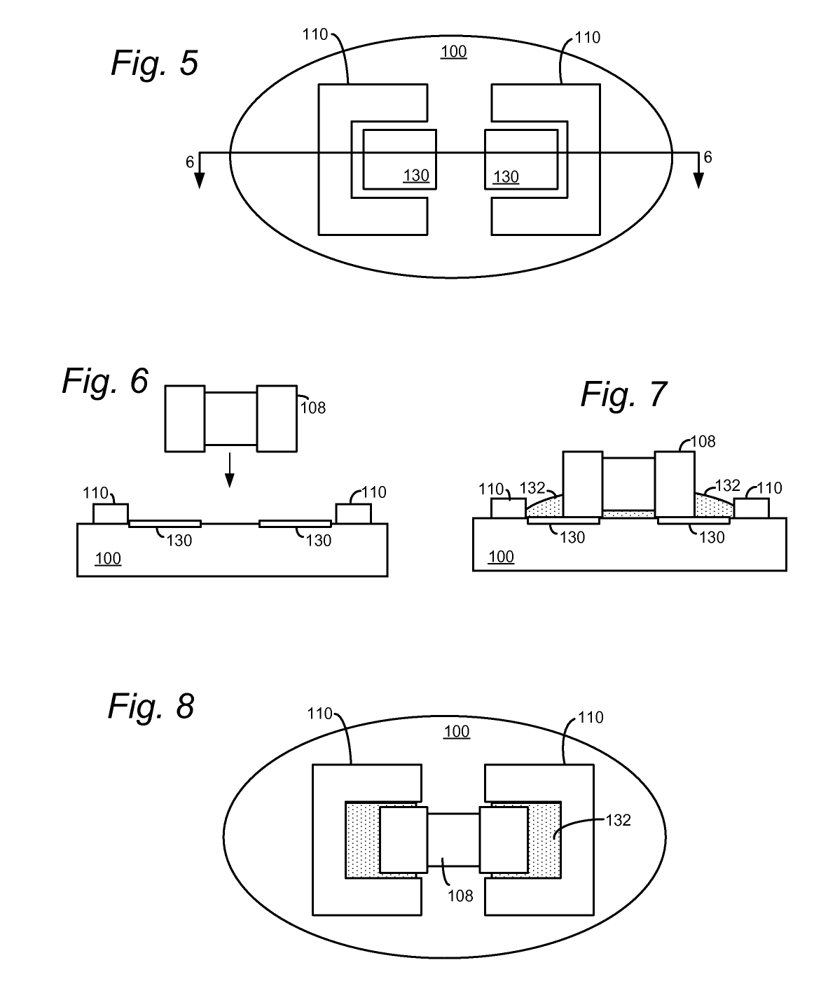

As explained in the Background of the Invention section, solder bleed may be detrimental to the operation of a semiconductor package formed from leadframe 100. Therefore, embodiments of the present invention may further include solder bleed barricades 110 for ensuring that solder applied on contact pads 130 remains only in a desired area on, and possibly adjacent to, contact pads 130. A pair of solder bleed barricades 110 are more clearly seen in the partial top view of leadframe 100 shown in FIG. 5. One or more barricades may surround or partially surround a pair of contact pads adapted to receive a single passive component 108, as in the example of FIG. 5. Alternatively, one or more barricades may surround or partially surround a single contact pad adapted to receive a single passive component 108.

Barricades 110 may be formed of an electrically insulating material, such as for example solder mask, an adhesive film or a polyimide tape. Barricades 110 may be formed on the surface of leadframe 100 by a variety of processes, including for example printing, lamination, or a variety of other deposition processes. Where barricades 110 are a polyimide film, they may be applied to the surface of leadframe 100 by a known adhesive. In the embodiments shown in the figures, passive components 108 and solder bleed barricades 110 are provided on the same side of leadframe 100 as semiconductor die 102, 104. It is understood that the passive components 108 and solder bleed barricades 110 may be provided on an opposite side of the leadframe from semiconductor die 102 and/or 104 in alternative embodiments of the present invention.

In the embodiments shown in FIG. 5, solder bleed barricades 110 may be a pair of U-shaped structures facing each other and surrounding a pair of contact pads 130. The width of each portion of U-shaped barricades 110 surrounding contact pads 130 may vary in alternative embodiments, but may for example be between 15 μm and 75 μm wide. It is understood that the width of each portion of barricades 110 may be less than 15 μm and greater than 75 μm in further embodiments. The height of barricades 110 above the surface of leadframe 100 may be less than or equal to the height of passive components 108 above the surface of leadframe 100 in embodiments of the invention. It is understood that the height of barricades 110 may be greater than the height of passive components 108 above the surface of leadframe 100 in further embodiments of the present invention.

Instead of a pair of U-shaped formations, solder bleed barricade 110 may alternatively be a raised rectangular wall surrounding the two contact pads 130 on all sides. Other shapes for solder bleed barricade 110 are contemplated.

Referring now to FIGS. 6 through 8, after a solder material 132 is applied to leadframe 100, passive component 108 may be seated on contact pads 130 between barricades 110 and the solder may be cured in a reflow process as is known in the art. Barricades 110 ensure that the solder material stays only where desired on, and possibly adjacent to, the contact pads 130 during the reflow process.

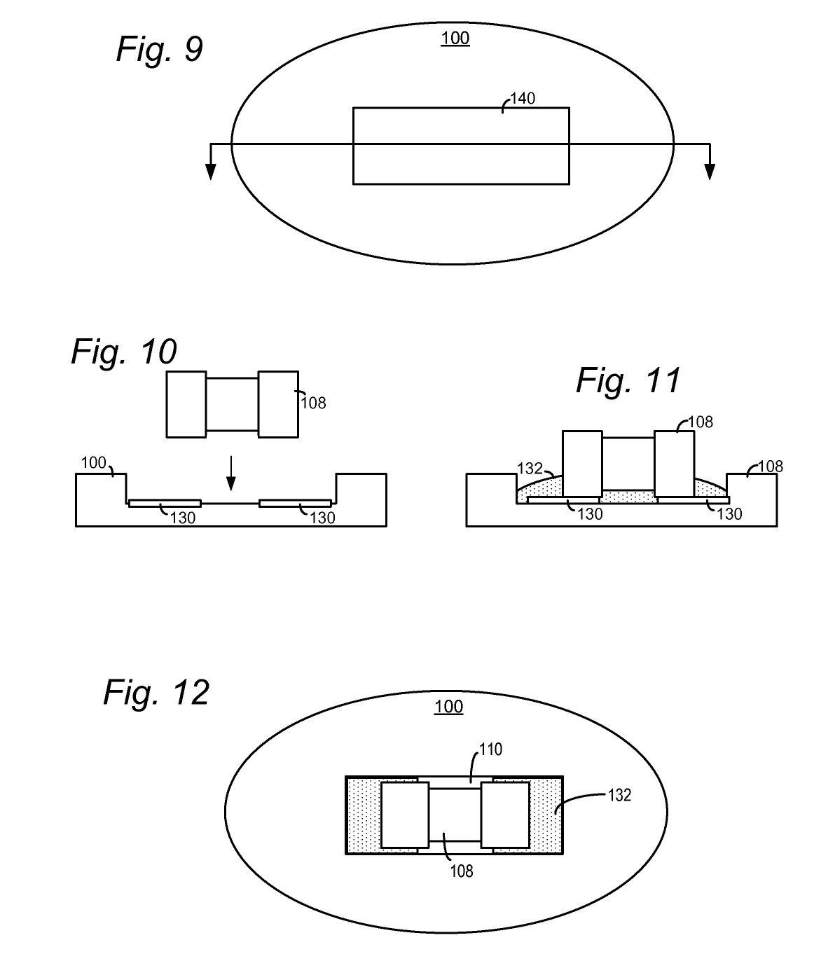

In the embodiments described above, a raised barricade is formed on the surface of leadframe 100 in order to contain solder material 132 in a desired location. In the alternative embodiment of FIGS. 9 through 12, instead of a raised wall, a recessed section 140 is formed partially down into the surface of leadframe 100. A variety of half-etch processes are known for forming recessed section 140 partially down into the surface of leadframe 100. Such processes include laser etching, chemical etching, routing, etc. After the recessed section 140 is formed in leadframe 100, contact pads 130 may be defined within recessed section 140 as shown in FIGS. 9 and 10 for receiving passive component 108.

Referring now to FIGS. 10 through 12, after a solder material 132 is applied to leadframe 100, passive component 108 may be seated on contact pads 130 within recessed section 140, and the solder may be cured in a reflow process as is known in the art. Recessed section 140 ensures that the solder material stays only where desired on, and possibly adjacent to, the contact pads 130 during the reflow process.

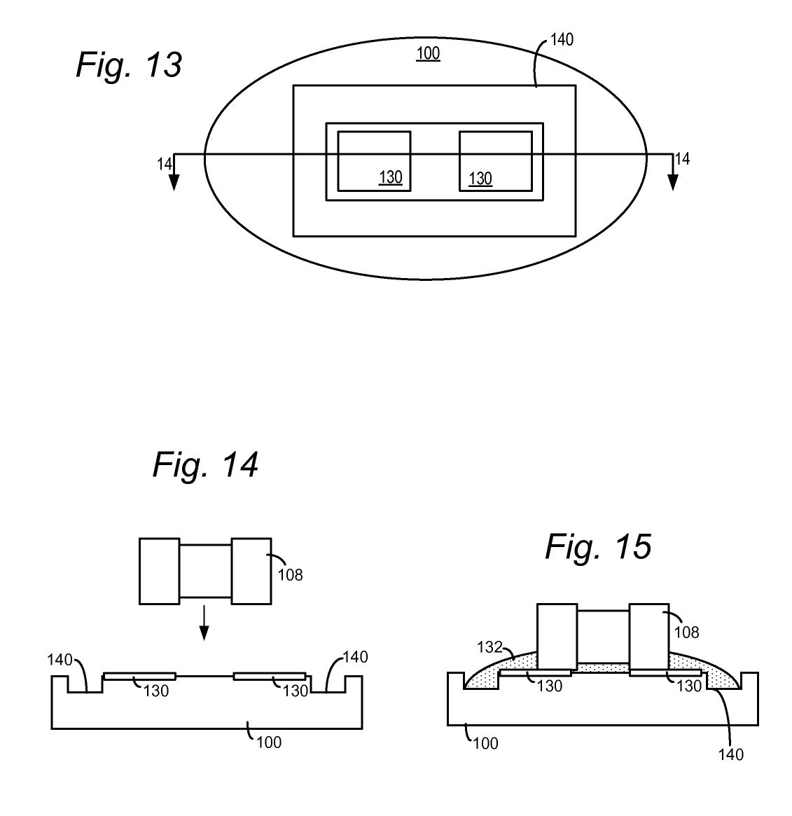

In the embodiments shown in FIGS. 9 through 12, recessed section 140 is a rectangle including contact pads 130. It is understood that recesses of the variety of other shapes may be formed in leadframe 100 to contain solder material 132 in a desired location. For example, in one further embodiment shown in FIGS. 13 through 15, recessed section 140 may be a rectangular ring formed in the surface of leadframe 100, surrounding contact pads 130 on an upper surface of leadframe 100. In this embodiment, recessed portions 140 perform as a moat capturing any solder paste which may flow away from contact pads 130. Instead of a rectangular recess as shown in FIGS. 13 through 15, a pair of U-shaped recesses may be formed. Such U-shaped recesses may have the same shape as barricades 110. However, instead of extending above the surface of leadframe 100 they are formed down into the surface of leadframe 100.

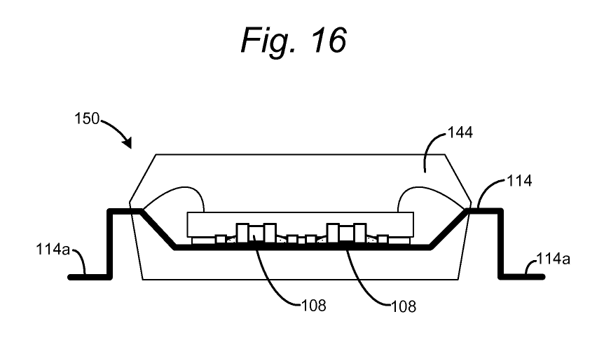

Once the die 102, 104 have been affixed and wire bonded, and the passive component(s) 108 have been affixed as described above, the leadframe, die and components may be encapsulated with a molding compound 144 to form a completed portable memory package 150 as shown in FIG. 16. Molding compound 144 may be an epoxy such as for example available from Sumitomo Corp. and Nitto Denko Corp., both having headquarters in Japan. Other molding compounds from other manufacturers are contemplated. The molding compound 144 may be applied according to various processes, including by transfer molding or injection molding techniques to form package 150. Ends 114a of leads 114 protrude from molding compound 144 and may be surface mounted to a host device such as a printed circuit board to electrically and physically couple the package 150 to the host device.

The above-described semiconductor die and leadframe may be used to form a TSOP 48-pin configuration. It is understood however that the number of pins and the type of leadframe package may vary significantly in alternative embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of fabricating a portable memory, comprising the steps of:
(a) positioning one or more passive components on one or more pads on a leadframe;
(b) soldering the one or more passive components on the leadframe with a solder material; and
(c) preventing bleeding of the solder material outside of an area adjacent the one or more pads by at least one of:
(c1) forming one or more barricades on and above a surface of the leadframe around the one or more pads, and
(c2) forming a recessed section within the surface of the leadframe around the one or more pads.

2. The method of claim 1, said step (c1) of forming one or more barricades comprising the step of forming a barricade on three sides of a pad of the one or more pads.

3. The method of claim 1, said step (c1) of forming one or more barricades comprising the step of forming a barricade around four sides of the one or more pads.

4. The method of claim 1, said step (c1) of forming one or more barricades comprising the step of forming the one or more barricades of an electrically insulating material.

5. The method of claim 4, said step of forming the one or more barricades of an electrically insulating material comprising the step of forming the one or more barricades of one of solder mask and a polyimide tape.

6. The method of claim 1, said step (c1) of forming one or more barricades comprising the step of forming the one or more barricades by one of printing, lamination or deposition processes.

7. The method of claim 1, said step (c2) of forming a recessed section within the surface of the leadframe comprising the step of forming a recessed section within which the one or more pads are provided.

8. The method of claim 1, further comprising the step of forming the one or more pads in an upper surface of the leadframe, said step (c2) of forming a recessed section within the surface of the leadframe comprising the step of forming a recessed section around the one or more pads in the upper surface of the leadframe.

9. The method of claim 1, said step (c2) of forming a recessed section within the surface of the leadframe comprising the step of etching the leadframe to form the recessed section in the leadframe.

10. The method of claim 9, said step of etching the leadframe to form the recessed section in the leadframe comprising the step of etching the leadframe with a laser or chemically etching the leadframe.

11. The method of claim 1, said step (c2) of forming a recessed section within the surface of the leadframe comprising the step of routing the leadframe to form the recessed section in the leadframe.

12. The method of claim 1, further comprising the step (d) of electrically and physically coupling one or more semiconductor die to the leadframe.

13. The method of claim 12, further comprising the step (e) of encapsulating the leadframe, one or more semiconductor die and one or more passive components in a molding compound.

14. A method of fabricating a portable memory, comprising the steps of:
(a) forming one or more barricades on a leadframe at least partially surrounding a location for receiving one or more passive components; and
(b) soldering the one or more passive components to the location with a solder material, the one or more barricades formed in said step (a) preventing a flow of the solder material beyond the one or more barricades.

15. The method of claim 14, said step (a) of forming one or more barricades on a leadframe at least partially surrounding a location for receiving one or more passive components comprising the step of forming a barricade on three sides of a location for receiving a single passive component.

16. The method of claim 14, said step (a) of forming one or more barricades on a leadframe at least partially surrounding a location for receiving one or more passive components comprising the step of forming a barricade around four sides of a location for receiving one or more passive components.

17. The method of claim 14, said step (a) of forming one or more barricades on a leadframe at least partially surrounding a location for receiving one or more passive components comprising the step of forming a barricade above a surface of the leadframe to a height less than or equal to a height of the one or more passive components above the leadframe.

18. The method of claim 14, said step (a) of forming one or more barricades on a leadframe at least partially surrounding a location for receiving one or more passive components comprising the step of forming the one or more barricades of an electrically insulating material.

19. The method of claim 18, said step (a) of forming the one or more barricades of an electrically insulating material comprising the step of forming the one or more barricades of one of solder mask and a polyimide tape.

20. The method of claim 14, said step (a) of forming one or more barricades on a leadframe at least partially surrounding a location for receiving one or more passive components comprising the step of forming the one or more barricades by one of printing, lamination or deposition processes.

21. The method of claim 14, further comprising the step (c) of electrically and physically coupling one or more semiconductor die to the leadframe.

22. The method of claim 21, further comprising the step of encapsulating the leadframe, one or more semiconductor die and one or more passive components in a molding compound.

23. A method of fabricating a portable memory, comprising the steps of:
(a) forming one or more recessed sections partially down into a planar surface of the leadframe at least partially surrounding a location for receiving one or more passive components; and
(b) soldering the passive component to the location with a solder material, the one or more recessed sections formed in said step (a) preventing a flow of the solder material beyond the one or more recessed sections.

24. The method of claim 23, said step (a) of forming one or more recessed sections partially down into a planar surface of the leadframe at least partially surrounding a location for receiving one or more passive components comprising the step of forming a recessed section around four sides of the location for receiving one or more passive components.

25. The method of claim 24, wherein the passive component is received and mounted within the recessed section.

26. The method of claim 24, wherein the passive component is mounted on the planar surface of the leadframe, said step (a) of forming one or more recessed sections partially down into a planar surface of the leadframe at least partially surrounding a location for receiving one or more passive components comprising the step of forming a moat around the location for receiving the one or more passive components.

27. The method of claim 23, said step (a) of forming one or more recessed sections partially down into a planar surface of the leadframe at least partially surrounding a location for receiving one or more passive components comprising the step of etching the leadframe to form the one or more recessed sections in the leadframe.

28. The method of claim 27, said step of etching the leadframe to form the one or more recessed sections in the leadframe comprising the step of etching the leadframe with a laser or chemically etching the leadframe.

29. The method of claim 23, said step (a) of forming one or more recessed sections partially down into a planar surface of the leadframe at least partially surrounding a location for receiving one or more passive components comprising the step of routing the leadframe to form the one or more recessed sections in the leadframe.

30. The method of claim 23, further comprising the step (c) of electrically and physically coupling one or more semiconductor die to the leadframe.

31. The method of claim 30, further comprising the step of encapsulating the leadframe, one or more semiconductor die and one or more passive components in a molding compound.
